(19) United States
(12) Patent Application Publication
(10) Pub. No.: US 2024/0329114 A1
(43) Pub. Date: Oct. 3, 2024

(54) DEVICE UNDER TEST (DUT) STRUCTURES IN FILL REGIONS OF PRODUCT DIE FOR VOLTAGE CONTRAST (VC) DEFECT DETECTION FOR IMPROVED YIELD LEARNING

(71) Applicant: Intel Corporation, Santa Clara, CA (US)

(72) Inventors: Sairam Subramanian, Portland, OR (US); Amit Paliwal, Hillsboro, OR (US); Xiao Wen, Beaverton, OR (US); Dipto Thakurta, Portland, OR (US); Manish Sharma, Portland, OR (US); Daniel Murray, Portland, OR (US)

(21) Appl. No.: 18/128,733

(22) Filed: Mar. 30, 2023

(51) Int. Cl. G01R 31/28

(52) U.S. Cl. CPC G01R 31/2851

(57) ABSTRACT

An integrated circuit on a production die comprises a device under test (DUT) cell array formed in a fill region on the production die, the DUT cell array comprising a plurality of DUT transistor structures configured for voltage contrast (VC) detection of electrical opens on the production die. The DUT transistor structures comprise one or more vias that are not located on power lines or signal lines, such that the DUT transistor structures are not connected to each other or to the electrically functioning transistors. A guard ring buffer is formed at a transition between the active transistor region and the DUT cell array.

### TECHNICAL FIELD

Embodiments of the disclosure are in the field of integrated circuits and, in particular, to the use of device under test (DUT) structures in fill regions of product die for voltage contrast (VC) defect detection for improved yield learning.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and state-of-the-art fabrication processes may limit the possibility to further extend them into the sub-10 nm range. Consequently, fabrication of the functional components needed for future technology nodes may require the introduction of new methodologies or the integration of new technologies in current fabrication processes or in place of current fabrication processes.

### BRIEF DESCRIPTION OF THE DRAWINGS

FIG. 1 is a transmission electron microscope (TEM) image showing a cross-section of an integrated circuit structure to illustrate a fabrication defect due to an electrical open or short.

FIG. 2 illustrates a VC image showing electrical defects in in an integrated circuit, where a dark pixels in VC image indicates the presence of an electrical defect.

FIG. 3 is a diagram illustrating integrated circuit structures on a production die in which conventional dummy cells in fill regions of the product die are replaced with DUT transistor structures or structures for VC imaging.

FIGS. 4A and 4B are layouts illustrating an example DUT cell array and occupation of DUT cell arrays in fill regions of a product die for VC defect detection, respectively.

FIG. 5 illustrates a flow diagram for providing DUT cells in fill regions of product die in accordance with the disclosed embodiments.

FIGS. 6A and 6B are top views of a wafer and dies that include one or more DUT transistor structures for VC image detection of electrical opens, in accordance with one or more of the embodiments disclosed herein.

FIG. 7 illustrates a block diagram of an electronic system, in accordance with an embodiment of the present disclosure.

FIG. 8 is a cross-sectional side view of an integrated circuit (IC) device assembly that may include one or more DUT transistor structures for VC image detection of electrical opens, in accordance with one or more of the embodiments disclosed herein.

FIG. 9 illustrates a computing device in accordance with one implementation of the disclosure.

### DESCRIPTION OF THE EMBODIMENTS

Use device under test (DUT) structures in fill regions of product die for voltage contrast (VC) defect detection for improved yield learning is described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments described herein are directed to structures and architectures for the use of device under test (DUT) structures in fill regions of product die, wafers or chip, for voltage contrast (VC) defect detection for improved yield learning. Embodiments may include or pertain to manufacturing process technologies for various types of integrated circuit products for increased yield.

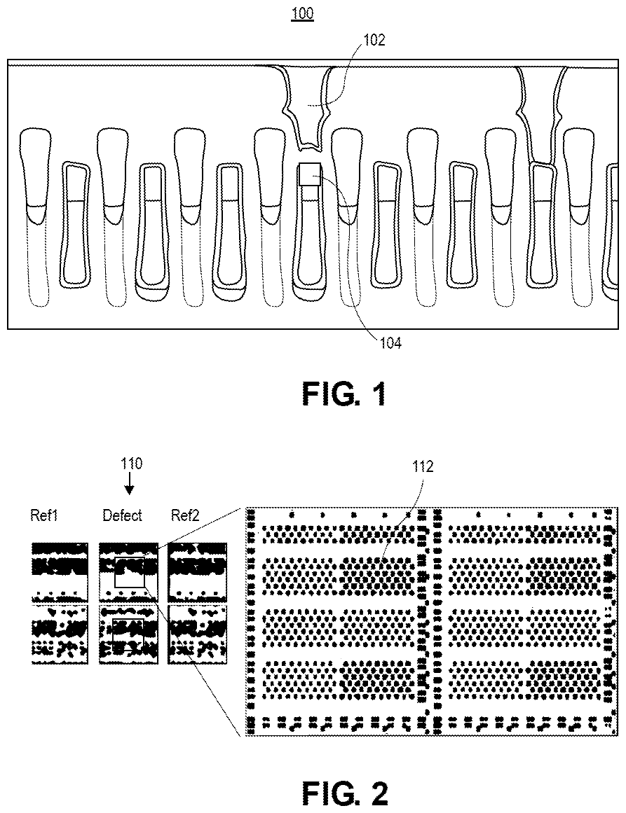

To provide context, FIG. 1 is a transmission electron microscope (TEM) image showing a cross-section of an integrated circuit structure 100 to illustrate a fabrication defect due to an electrical open or short. In the cross-section, a via 102 is shown formed over a gate 104. For a functioning device, via 102 should be in contact with the gate 104. However, the TEM image shows a defect in integrated circuit 100 caused by the via 102 being formed too shallow, which creates a gap between it and the gate 104. A similar type of defect occurs, for example, when a trench contact fails to form on epitaxial (epi) source or drain structures or when the epi fails to connect to a fin in a FinFET.

Electrical opens and shorts due are buried defects and present a major challenge for obtaining improved fabrication yields on production chips. Successful inline detection of electrical opens/shorts, such as via to gates or contacts to epi opens is notoriously difficult. Inline detection of electrical opens typically fails since electrical opens are buried defects that occur post contact metallization. As these defects are not detectable top down, the defects are typically not discovered until end of line (EOL) when fabrication is complete and tested. For example, processes have had to rely on end of line signals to detect such buried defects. Waiting for EOL is detrimental to yield learning as it adds 4-6 weeks to the readout of every experiment and hence directly impacts yield learning and product commits.

To solve this problem, some destructive Quick turn monitors (QTMs) have been developed that try to etch the epi through the contact space prior to contact metallization to determine if there is an oxide layer that prevents the etch. The QTMs perform unreliably as they are hard to engineer and this approach can only detect contact underetch, not missing contact metal. Further, destructive QTMs are expensive on product as these count towards wafer loss/line yield and drive up the cost of product starts. Also, detection of buried defects or modes is still a challenge on topical tools, and some QTMs have a very low probability of success on optical tools, e.g., for detection of polysilicon (end-to-end) ETE at a plug bottom or a via open due to gate metal etch out.

Detection of electrical shorts on production die/chips, as opposed to test chips, is severely limited or nonexistent, thereby slowing down product yield learning and development.

In accordance with one or more embodiments described herein, device under test (DUT) structures are used to take advantage of voltage contrast (VC) mode for detection of electrical opens/shorts in production chips caused by a fabrication process. The disclosed embodiments provide inline detection to the difficult problem of electrical defects/opens and trims 4-6 weeks of yield learning time by not having to run potential skews for solutions to end of line. The VC test is also non-destructive so this can be run on production wafers that can go to end of line thereby minimizing cost and also establishing correlations to known yield signals at end of line.

VC mode is a technique used in semiconductor inspection and analysis to detect defects or irregularities in integrated circuits. VC mode involves applying a voltage to a specific layer of the semiconductor device and observing the resulting contrast in the image produced by an electron microscope. In VC mode, a small voltage is applied to a specific layer of the semiconductor device using a probe. The voltage causes a change in the electrical potential of the layer, which in turn causes changes in the electron beam as it passes through the layer. These changes in the electron beam can be detected by an electron microscope and used to create a VC image of the device. The VC image shows areas where the voltage contrast is high, indicating areas of the device where there may be defects or irregularities.

FIG. 2, as an example, illustrates a VC image 110 showing electrical defects in in an integrated circuit, where a dark pixels in VC image 110 indicates the presence of an electrical defect. In this example, an enlarged view of the VC image 110 shows a plurality of vias 112 that appear as an array of dots. In the VC image 110, vias that have via open defects appear dark instead of bright.

The disclosed embodiments utilize DUT structures created for VC analysis that can be used to detect electrical opens/shorts. The dummy transistor structures are designed to take advantage of the fact that in VC mode, electron beam tools can distinguish between grounded and floating features. This technique is especially useful in detecting defects that are buried or hidden and are not otherwise accessible for detection through optical metrology. The DUT structures may be fabricated alongside active structures on whitespace or dummy fill regions of a production die and the production die is examined in VC mode to identify electrical defects. In the resulting VC images, grounded features appear bright whereas floated appear darker under the right polarity.

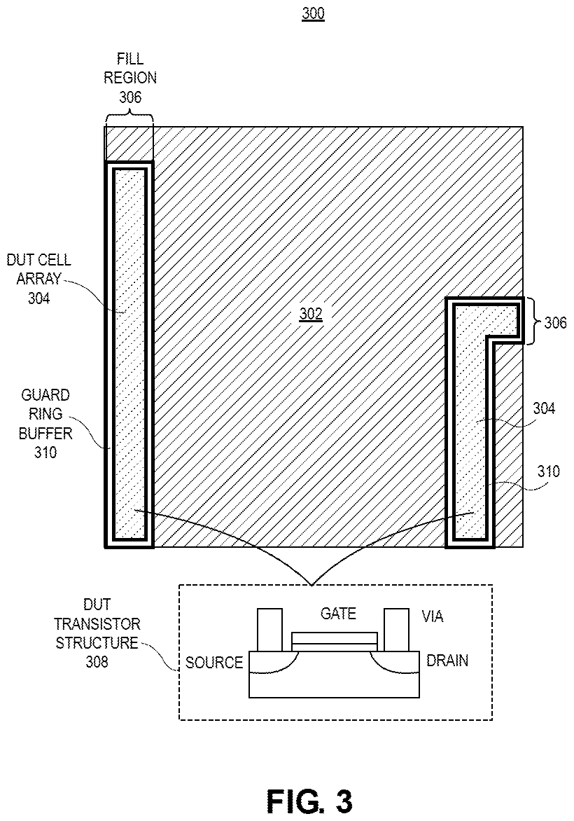

FIG. 3 is a diagram illustrating integrated circuit structures on a production die in which conventional dummy cells in fill regions of the product die are replaced with DUT transistor structures for VC imaging. The DUT transistor structures are used to identify various types of defects in the product die in accordance with the disclosed embodiments. The production die 300 comprises an active transistor region 302 of electrically functioning transistors on the production die 300. According to embodiments, at least one DUT cell array 304 is located in a fill region 306 on the production die 300 in place of conventional dummy cells. The DUT cell array 304 comprises a plurality of DUT transistor structures 308 configured for voltage contrast (VC) detection of electrical opens on the production die 302. The DUT transistor structures 308 comprising the DUT cell array 304 include one or more vias that are not located on power lines or signal lines, so that the DUT transistor structures 308 are not connected to each other or to the electrically functioning transistors.

FIG. 3 further shows an example DUT transistor structure 308. The example DUT transistor structure 308 includes at least a source and a drain on either side of a gate, and at least one via on either the source or drain as long the DUT transistor structure 308 has a grounding path to substrate.

The DUT transistor structures 308 are fabricated on the production die, chip, or wafer using the same materials used to fabricate active transistor region. The DUT transistor structures 308 may span multiple layers from diffusion on up to a full stack. However, the DUT transistor structures 308 are not electrically connected to other components in the IC structure and serve only for detection of electrical opens/shorts. Subsequent to contact metallization, VC mode is performed. If the DUT transistor structures 308 have no open defects, the DUT transistor structures 308 will appear bright in the resulting VC image, as shown in FIG. 2.

In addition, a guard ring buffer 310 is located at a transition between the active transistor region 302 and the DUT cell array 304. In some embodiments, the guard ring buffer 310 may at least partially surround boundaries of the DUT cell array 304, while in other embodiments, the guard ring buffer 310 completely surrounds boundaries of the DUT cell array 304. The guard ring buffer 310 may have a width of approximately 3-5 poly pitches for a particular to technology node. For example, for one example technology node, the guard ring buffer may be 135-250 nm in width.

According to the disclosed embodiments, the DUT transistor structures 308 can be used to identify various types of defects, such as trench contact (TCN) opens, via to gate opens (via G), via TCN opens, a poly end-to-end shorts, metal zero end-to-end shorts, metal zero-to-via shorts, and the like or a combination thereof, depending on a given yield parameter.

By re-purposing the unused filler regions of product die for DUT transistor structures 308, which are standard design rule compatible for layouts and densities, the disclosed embodiments ensure no additional footprint is added to the die, with the advantage of inline e-beam detection of buried opens/shorts. Availability of such DUT transistor structures 308 on product die/chips is helpful for debugging, solving yield problems and product to test chip deltas, and ensuring commitment to yield roadmaps. The VC test is also non-destructive so this can be run on production wafers that can go to end of line thereby minimizing cost and also establishing correlations to known yield signals at end of line. Consequently, the DUT transistor structures 308 in whitespaces of product die enable earlier and faster troubleshooting and resolution of yield problem.

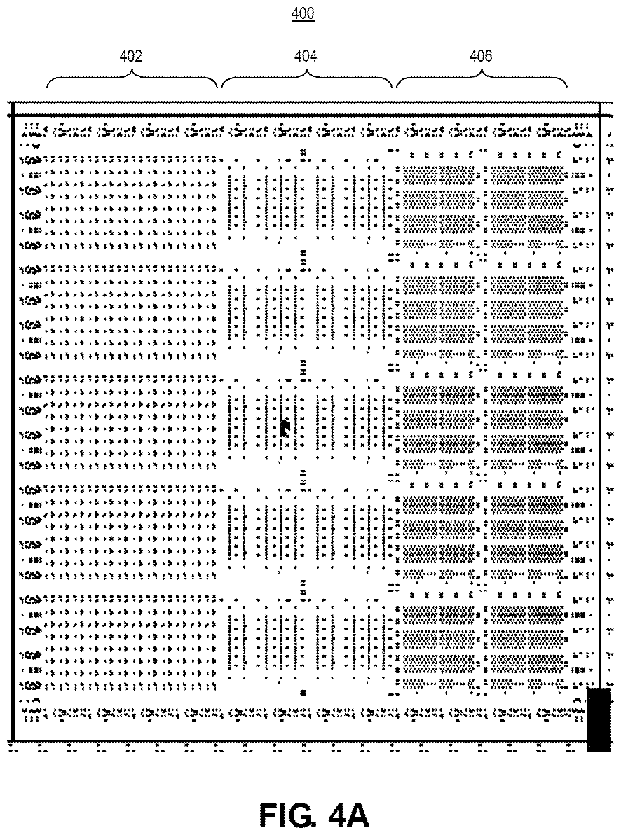

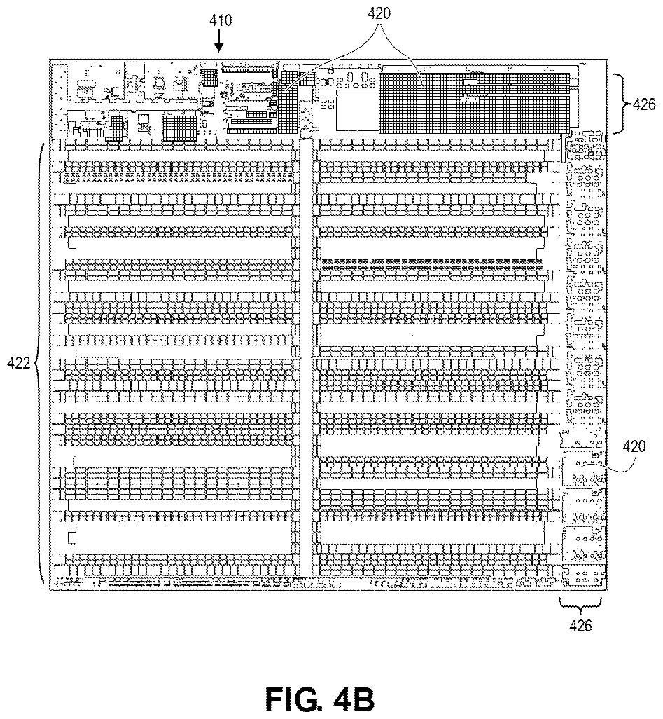

FIGS. 4A and 4B are layouts illustrating an example DUT cell array and occupation of DUT cell arrays in fill regions of a product die for VC defect detection, respectively. In the example of FIG. 4A, a single large DUT cell array 400 is shown in which different defect modes are targeted by different DUT transistor structures 308. The DUT cell array 400 may be fabricated by replicating DUT transistor structures 308. In one example, the DUT cell array 420 may be at least approximately 5×5 μm wide. The DUT transistor structures 308 comprising the DUT cell array 400 are organized into columns. For example, one column 402 of DUT transistor structures may be designed to target viaG opens, a second column 404 may be designed to target contact short (TCN_STS), and a third column 406 may be designed to target gate end-to-end (gate_ETE) shorts. Although three columns of different DUT transistor structures are shown, the DUT cell array 400 may include any number and arrangement of different DUT transistor structures for a particular use case.

FIG. 4B illustrates another example showing a product die 410 having active regions 422 and large DUT cell arrays 420. The DUT cell arrays 420 comprising DUT transistor structures 308 are shown interspersed in fill regions 426 of the product die 410 in place of conventional dummy cells to test the yield of a manufacturing process.

A method of fabricating DUT integrated circuit structures in fill regions of product die for voltage contrast (VC) defect detection may include forming an active transistor region of electrically functioning transistors on the production die. A device under test (DUT) cell array is formed in a fill region on the production die, the DUT cell array comprising a plurality of DUT transistor structures configured for voltage contrast (VC) detection of electrical opens on the production die. The DUT transistor structures comprise one or more vias that are not located on power lines or signal lines, such that the DUT transistor structures are not connected to each other or to the electrically functioning transistors. A guard ring buffer is formed at a transition between the active transistor region and the DUT cell array.

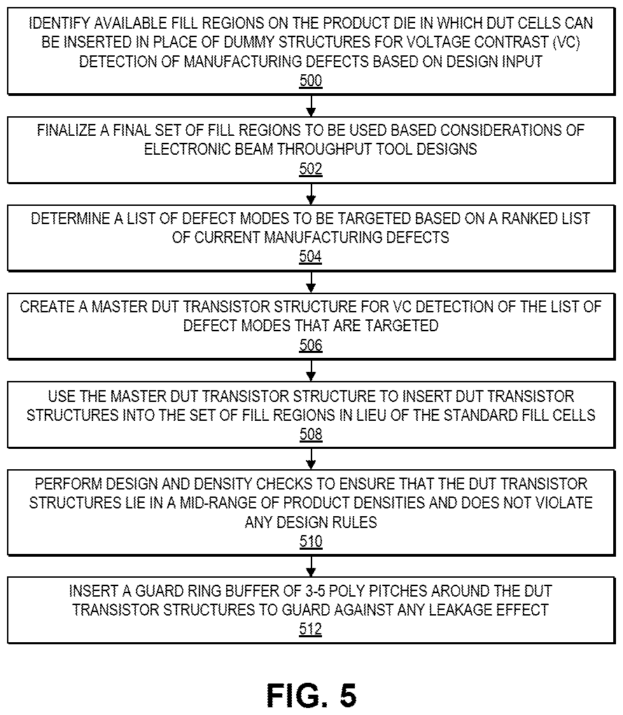

FIG. 5 illustrates a flow diagram for providing DUT cells in fill regions of product die in accordance with the disclosed embodiments. The process may begin by identifying available fill regions on the product die in which DUT cells can be inserted in place of dummy structures for voltage contrast (VC) detection of manufacturing defects based on design input (block 500). A final set of fill regions to be used is then finalized based on considerations of electronic beam (e-beam) throughput tool designs (block 502). A list of defect modes to be targeted is determined based on a ranked list of current manufacturing defects (block 504). Any roadmap projections for the product intercept may also be considered. In one embodiment, the top one to three defect modes for targeting are selected from the ranked list of current manufacturing defects. Once this is done, a master DUT transistor structure is created for VC detection of the list of defect modes that are targeted (block 506). For example, FIG. 4A show DUT transistor structures for insertion into a product die that targets detection of viaG opens, gate_ETE shorts and TCN_STS shorts for that product.

Once the master DUT transistor structure is designed, the master DUT transistor structure is used to insert DUT transistor structures into the set of fill regions in lieu of the standard fill cells (block 508). In one embodiment, this operation is performed by a custom fill flow algorithm. Additionally or alternatively, the operation may be performed by a manual process. At every step, design and density checks are performed to ensure that the new DUT transistor structures lie in a mid-range of product densities and does not violate any design rules (block 510). Additionally, checks may be performed to ensure that there is no un-intentional shorting of other signal or power lines used in the DUT transistor structures. The insertion of vias on metal layers which carry power or signal lines are deliberately skipped in the DUT transistor structures to guard against shorts. Finally, a guard ring buffer of 3-5 poly pitches is inserted around the DUT transistor structures to guard against any leakage effect (block 512).

This method can be applied to target any defect modes that are detectable by VC. The above method can also be translated to test-chips where area is at a premium—where any unused whitespace/fill region is repurposed with DUT transistor structures. One such example is shown in FIG. 5 of a chip where the yellow regions denote whitespace repurposed for VC using the method described above.

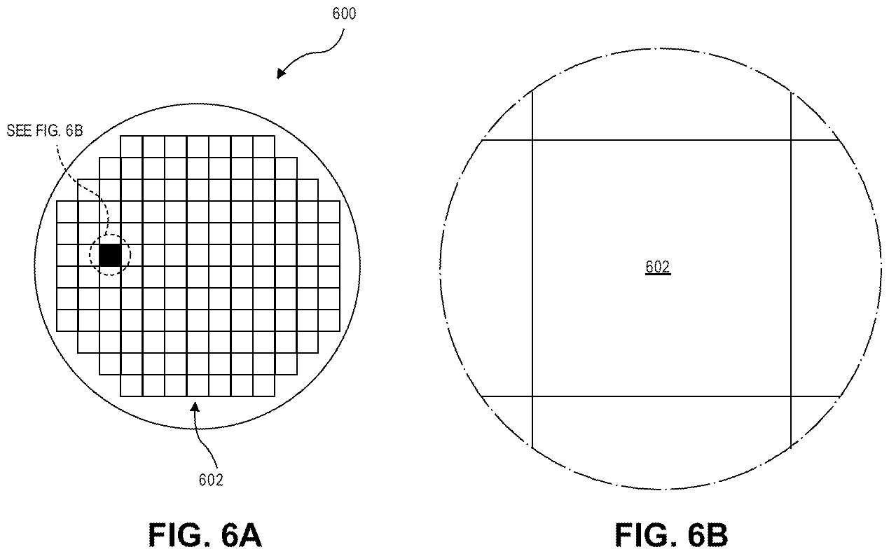

The integrated circuit structures described herein may be included in an electronic device. As an example of one such apparatus, FIGS. 6A and 6B are top views of a wafer and dies that include one or more DUT transistor structures for VC image detection of electrical opens, in accordance with one or more of the embodiments disclosed herein.

Referring to FIGS. 6A and 6B, a wafer 600 may be composed of semiconductor material and may include one or more dies 602 having integrated circuit (IC) structures formed on a surface of the wafer 600. Each of the dies 602 may be a repeating unit of a semiconductor product that includes any suitable IC (e.g., ICs including one or more DUT transistor structures for VC image detection of electrical opens, such as described above. After the fabrication of the semiconductor product is complete, the wafer 600 may undergo a singulation process in which each of the dies 602 is separated from one another to provide discrete “chips” of the semiconductor product. In particular, structures that include embedded non-volatile memory structures having an independently scaled selector as disclosed herein may take the form of the wafer 600 (e.g., not singulated) or the form of the die 602 (e.g., singulated). The die 602 may include one or more embedded non-volatile memory structures based independently scaled selectors and/or supporting circuitry to route electrical signals, as well as any other IC components. In some embodiments, the wafer 600 or the die 602 may include an additional memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

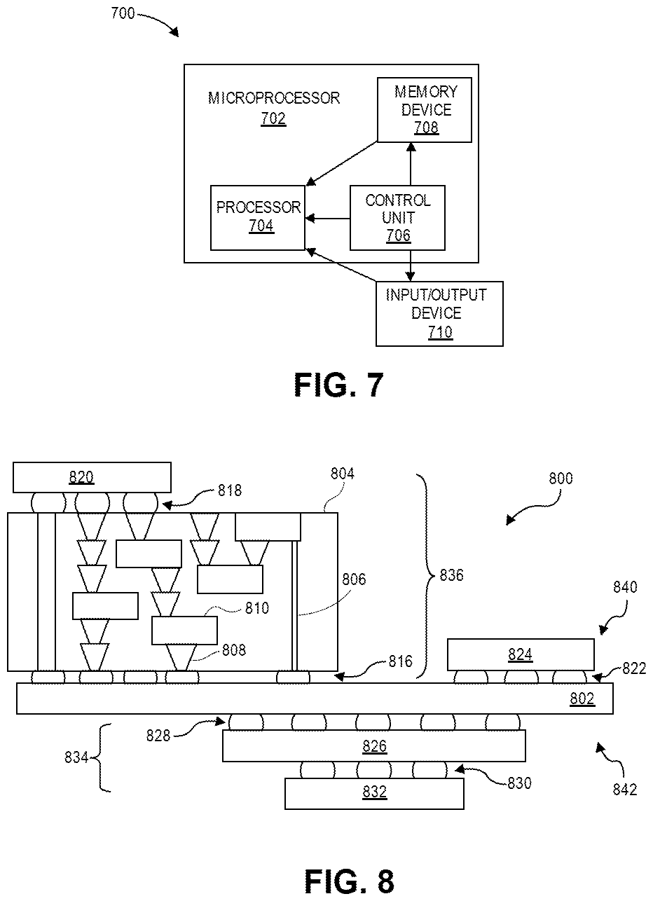

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations which are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a non-volatile memory cell as described in the present description. In an embodiment, the memory device 708 is embedded in the microprocessor 702, as depicted in FIG. 7. In an embodiment, the processor 704, or another component of electronic system 700, includes one or more DUT transistor structures for VC image detection of electrical opens, such as those described herein.

FIG. 8 is a cross-sectional side view of an integrated circuit (IC) device assembly that may include one or more DUT transistor structures for VC image detection of electrical opens, in accordance with one or more of the embodiments disclosed herein.

Referring to FIG. 8, an IC device assembly 800 includes components having one or more integrated circuit structures described herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802. Generally, components may be disposed on one or both faces 840 and 842. In particular, any suitable ones of the components of the IC device assembly 800 may include a number of DUT transistor structures for VC image detection of electrical opens, such as disclosed herein.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804. It is to be appreciated that additional interposers may be coupled to the interposer 804. The interposer 804 may provide an intervening substrate used to bridge the circuit board 802 and the IC package 820. The IC package 820 may be or include, for example, a die (the die 602 of FIG. 6B), or any other suitable component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804. In other embodiments, the IC package 820 and the circuit board 802 may be attached to a same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 810 and vias 808, including but not limited to through-silicon vias (TSVs) 806. The interposer 804 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

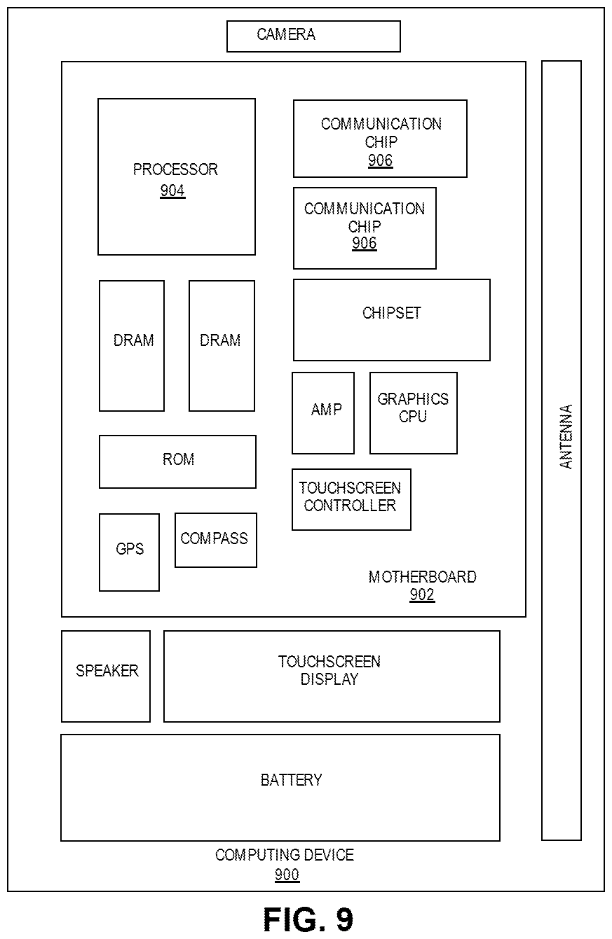

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor includes one or more DUT transistor structures for VC image detection of electrical opens, in accordance with implementations of embodiments of the disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the disclosure, the integrated circuit die of the communication chip includes one or more DUT transistor structures for VC image detection of electrical opens, in accordance with implementations of embodiments of the disclosure.

In further implementations, another component housed within the computing device 900 may contain an integrated circuit die that includes one or more DUT transistor structures for VC image detection of electrical opens, in accordance with implementations of embodiments of the disclosure.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Thus, embodiments described herein include DUT transistor structures for VC image detection of electrical opens. The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example embodiment 1: An integrated circuit on a production die comprises a device under test (DUT) cell array formed in a fill region on the production die, the DUT cell array comprising a plurality of DUT transistor structures configured for voltage contrast (VC) detection of electrical opens on the production die. The DUT transistor structures comprise one or more vias that are not located on power lines or signal lines, such that the DUT transistor structures are not connected to each other or to the electrically functioning transistors. A guard ring buffer is formed at a transition between the active transistor region and the DUT cell array.
Example embodiment 2: The embodiment of example 1, wherein the guard ring buffer at least a partially surrounds the DUT cell array.
Example embodiment 3: The embodiment of example 1 or 2, wherein the guard ring buffer surrounds the DUT cell array.
Example embodiment 4: The embodiment of example 1, 2, or 3, wherein the guard ring buffer has a width of approximately 3-5 poly pitches.
Example embodiment 5: The embodiment of example 1, 2, 3, or 4, wherein the DUT cell array is fabricated on the production die using materials used to fabricate the active transistor region.
Example embodiment 6: The embodiment of example 1, 2, 3, 4, or 5, wherein the DUT transistor structures are used to identify various types of defects, including trench contact (TCN) opens, via to gate opens (via G), via TCN opens, a poly end-to-end shorts, metal zero end-to-end shorts, metal zero-to-via shorts or a combination thereof.
Example embodiment 7: The embodiment of example 1, 2, 3, 4, 5, or 6, wherein the DUT transistor structures are standard design rule compatible for layouts and densities.
Example embodiment 8: An integrated circuit (IC) assembly comprises a circuit board and an active transistor region of electrically functioning transistors on the circuit board. A device under test (DUT) cell array is formed in a fill region, the DUT cell array comprising a plurality of DUT transistor structures configured for voltage contrast (VC) detection of electrical opens on the production die. The DUT transistor structures comprise one or more vias that are not located on power lines or signal lines, such that the DUT transistor structures are not connected to each other or to the electrically functioning transistors. A guard ring buffer is formed at a transition between the active transistor region and the DUT cell array.
Example embodiment 9: The embodiment of example 8, wherein the guard ring buffer at least a partially surrounds the DUT cell array.
Example embodiment 10: The embodiment of example 8 or 9, wherein the guard ring buffer surrounds the DUT cell array.
Example embodiment 11: The embodiment of example 8, 9, or 10, wherein the guard ring buffer has a width of approximately 3-5 poly pitches.
Example embodiment 12: The embodiment of example 8, 9, 10, or 11, wherein the DUT cell array is fabricated using materials used to fabricate the active transistor region.
Example embodiment 13: The embodiment of example 8, 9, 10, 11, or 12, wherein the DUT transistor structures are used to identify various types of defects, including trench contact (TCN) opens, via to gate opens (via G), via TCN opens, a poly end-to-end shorts, metal zero end-to-end shorts, metal zero-to-via shorts or a combination thereof.
Example embodiment 14: The embodiment of example 8, 9, 10, 11, 12, or 13, wherein the DUT transistor structures are standard design rule compatible for layouts and densities.
Example embodiment 15: A method of providing device under test (DUT) structures in fill regions of product die for voltage contrast (VC) detection of manufacturing defects, the embodiment comprises identifying available fill regions on the product die in which DUT cells can be inserted in place of dummy structures for voltage contrast (VC) detection of manufacturing defects based on design input. A final set of fill regions to be used is finalized based on considerations of electronic beam throughput tool designs. A list of defect modes to be targeted is determined based on a ranked list of current manufacturing defects. A master DUT transistor structure is created for VC detection of the list of defect modes that are targeted. The master DUT transistor structure is used to insert DUT transistor structures into the set of fill regions in lieu of the standard fill cells. Design and density checks are performed to ensure that the DUT transistor structures lie in a mid-range of product densities and does not violate any design rules. A guard ring buffer of 3-5 poly pitches is inserted around the DUT transistor structures to guard against any leakage effect.
Example embodiment 16: The embodiment of example 15, wherein determining a list of defect modes to be targeted is further comprises selecting a top one to three defect modes for targeting from ranked list of current manufacturing defects.
Example embodiment 17: The embodiment of example 15 or 16, further comprising using a custom fill flow algorithm to insert the DUT transistor structures into the set of fill regions.
Example embodiment 18: The embodiment of example 15, 16, or 17, further comprising performing checks to ensure that there is no un-intentional shorting of other signal or power lines used in the DUT transistor structures.
Example embodiment 19: The embodiment of example 15, 16, 17, or 18, further comprising skipping insertion of vias on metal layers that carry power or signal lines in the DUT transistor structures.
Example embodiment 20: The embodiment of example 15, 16, 17, 18, or 19, further comprising inserting the guard ring buffer at 3-5 poly pitches.

What is claimed is:

1. An integrated circuit (IC) structure on a production die, comprising:
an active transistor region of electrically functioning transistors on the production die; a device under test (DUT) cell array in a fill region on the production die, the DUT cell array comprising a plurality of DUT transistor structures configured for voltage contrast (VC) detection of electrical opens on the production die, the DUT transistor structures comprising one or more vias that are not located on power lines or signal lines, such that the DUT transistor structures are not connected to each other or to the electrically functioning transistors; and
a guard ring buffer at a transition between the active transistor region and the DUT cell array.

2. The IC structure of claim 1, wherein the guard ring buffer at least a partially surrounds the DUT cell array.

3. The IC structure of claim 1, wherein the guard ring buffer surrounds the DUT cell array.

4. The IC structure of claim 1, wherein the guard ring buffer has a width of approximately 3-5 poly pitches.

5. The IC structure of claim 1, wherein the DUT cell array is fabricated on the production die using materials used to fabricate the active transistor region.

6. The IC structure of claim 1, wherein the DUT transistor structures are used to identify various types of defects, including trench contact (TCN) opens, via to gate opens (via G), via TCN opens, a poly end-to-end shorts, metal zero end-to-end shorts, metal zero-to-via shorts or a combination thereof.

7. The IC structure of claim 1, wherein the DUT transistor structures are standard design rule compatible for layouts and densities.

8. An integrated circuit (IC) assembly, comprising:
a circuit board;
an active transistor region of electrically functioning transistors on the circuit board;
a device under test (DUT) cell array in a fill region adjacent to the active transistor region, the DUT cell array comprising a plurality of DUT transistor structures configured for voltage contrast (VC) detection of electrical opens, the DUT transistor structures comprising one or more vias that are not located on power lines or signal lines, such that the DUT transistor structures are not connected to each other or to the electrically functioning transistors; and
a guard ring buffer at a transition between the active transistor region and the DUT cell array.

9. The IC structure of claim 8, wherein the guard ring buffer at least a partially surrounds the DUT cell array.

10. The IC structure of claim 8, wherein the guard ring buffer surrounds the DUT cell array.

11. The IC structure of claim 8, wherein the guard ring buffer has a width of approximately 3-5 poly pitches.

12. The IC structure of claim 8, wherein the DUT cell array is fabricated using materials used to fabricate the active transistor region.

13. The IC structure of claim 8, wherein the DUT transistor structures are used to identify various types of defects, including trench contact (TCN) opens, via to gate opens (via G), via TCN opens, a poly end-to-end shorts, metal zero end-to-end shorts, metal zero-to-via shorts or a combination thereof.

14. The IC structure of claim 8, wherein the DUT transistor structures are standard design rule compatible for layouts and densities.

15. A method of providing device under test (DUT) structures in fill regions of product die for voltage contrast (VC) detection of manufacturing defects, the method comprising:
identifying available fill regions on the product die in which DUT cells can be inserted in place of dummy structures for voltage contrast (VC) detection of manufacturing defects based on design input;
finalizing a final set of fill regions to be used based on considerations of electronic beam throughput tool designs;
determining a list of defect modes to be targeted based on a ranked list of current manufacturing defects;
creating a master DUT transistor structure for VC detection of the list of defect modes that are targeted;
using the master DUT transistor structure to insert DUT transistor structures into the set of fill regions in lieu of the standard fill cells;
performing design and density checks to ensure that the DUT transistor structures lie in a mid-range of product densities and does not violate any design rules; and
inserting a guard ring buffer of 3-5 poly pitches around the DUT transistor structures to guard against any leakage effect.

16. The method of claim 15, wherein determining a list of defect modes to be targeted is further comprises selecting a top one to three defect modes for targeting from ranked list of current manufacturing defects.

17. The method of claim 15, further comprising using a custom fill flow algorithm to insert the DUT transistor structures into the set of fill regions.

18. The method of claim 15, further comprising performing checks to ensure that there is no un-intentional shorting of other signal or power lines used in the DUT transistor structures.

19. The method of claim 15, further comprising skipping insertion of vias on metal layers that carry power or signal lines in the DUT transistor structures.

20. The method of claim 15, further comprising inserting the guard ring buffer at 3-5 poly pitches.
